(19) United States
(12) Patent Application Publication
(10) Pub. No.: US 2005/0275422 A1
(43) Pub. Date: Dec. 15, 2005

(54) Integrated circuit device with compliant bumps and testing method for testing the integrated circuit device

(76) Inventors: Song-Ping Luh, Hsin-Chu City (TW); Kun-Yung Huang, Hsin-Chu City (TW); Chung-Hung Wang, Hsin-Chu City (TW)

Correspondence Address: SEYFARTH SHAW LLP, 55 EAST MONROE STREET, SUITE 4200, CHICAGO, IL, 60603-5803, US

(21) Appl. No.: 10/962,885

(22) Filed: Oct. 12, 2004

(30) Foreign Application Priority Data
Jun. 11, 2004 (TW) 093116891

(51) Int. Cl. G01R 31/26

(52) U.S. Cl. 324/765

(57) ABSTRACT

A testing method for testing an integrated circuit device includes the steps of forming compliant bumps on bonding pads on a substrate of the device such that each of the compliant bumps has a polymeric body formed on a corresponding one of the bonding pads and a metal layer formed on the polymeric body, and such that the metal layer has a probe-contacting surface formed with a plurality of recesses, and testing electrical continuity between the metal layer of each of the compliant bumps and a corresponding circuit of the device by contacting a probe of a testing apparatus with the recessed probe-contacting surface of the metal layer.

### CROSS-REFERENCE TO RELATED APPLICATION

This application claims priority of Taiwanese application no. 093116891, filed on Jun. 11, 2004.

### BACKGROUND OF THE INVENTION

1. Field of the Invention

This invention relates to an integrated circuit device and a testing method for testing the integrated circuit device, more particularly to an integrated circuit device having compliant bumps, each of which has a rough surface to improve the probe needle tip sliding problem in the testing of conventional smooth surface compliant bumps bumped IC devices.

2. Description of the Related Art

FIG. 1 illustrates a conventional integrated circuit device, such as a wafer, that includes a substrate 93 having circuits built therein, a pattern of bonding pads 90 (only one pad is shown) formed on the substrate 93, a pad-extension layer 94 formed on each bonding pad 90, and a compliant bump 9 formed on the pad-extension layer 94 on each bonding pad 90 for subsequent package processing, such as Chip On Glass (COG) processing, and Chip On Film (COF) processing. The compliant bump 9 includes a polymeric body 91 formed on the respective bonding pad 90, and a metal layer 92 that is formed on an outer surface of the polymeric body 91 using sputtering techniques, and that is connected electrically to the pad-extension layer 94. The compliant bump 9 bumped IC device thus formed is required to undergo an electrical test for testing electrical continuity between the compliant bump 9 and the respective circuit in the substrate 93 using a probe 81 of a testing apparatus (not shown). The probe 81 is laid on and then over-driven against a probe-contacting surface 921 of the compliant bump 9 during the electrical test.

The conventional compliant bump bumped integrated circuit device is disadvantageous in that since the probe-contacting surface 921 of the compliant bump 9 is relatively smooth, the probe 81 tends to slip on the probe-contacting surface 921 of the compliant bump 9 during testing, which results in an increase in the testing time and an uncertainty in the testing results. In addition, slipping of the probe 81 on the probe-contacting surface 921 of the compliant bump 9 can scratch the metal layer 92, which, in turn, results in contamination of the probe 81. As a consequence, the probe 81 is required to be cleaned frequently.

### SUMMARY OF THE INVENTION

Therefore, the object of this invention is to provide an integrated circuit device with compliant bumps having roughened probe-contacting surfaces and a testing method that involves forming the roughened probe-contacting surfaces of the compliant bumps so as to overcome the aforesaid drawbacks of the prior art.

According to one aspect of the present invention, a testing method for testing electrical continuity between compliant bumps and circuits of an integrated circuit device is provided. The testing method includes the steps of: forming the compliant bumps on bonding pads on a substrate of the device such that each of the compliant bumps has a polymeric body formed on a corresponding one of the bonding pads and a metal layer formed on the polymeric body, and such that the metal layer has an probe-contacting surface formed with a plurality of recesses; and testing electrical continuity between the metal layer of each of the compliant bumps and a corresponding one of the circuits of the integrated circuit device by contacting a probe of a testing apparatus with the recessed probe-contacting surface of the metal layer which provides a surface roughness that is sufficient to prevent the probe from slipping on the probe-contacting surface of the metal layer during testing by virtue of the recesses formed in the probe-contacting surface of the metal layer.

According to another aspect of the present invention, an integrated circuit device comprises: a substrate having a pad-mounting surface and a plurality of bonding pads formed on the pad-mounting surface; and a plurality of compliant bumps formed respectively on the bonding pads. Each of the compliant bumps has a polymeric body formed on the respective one of the bonding pads, and a metal layer formed on the polymeric body. The metal layer of each of the compliant bumps has an probe-contacting surface that is formed with a plurality of recesses.

### BRIEF DESCRIPTION OF THE DRAWINGS

Other features and advantages of the present invention will become apparent in the following detailed description of the preferred embodiments of the invention, with reference to the accompanying drawings. In the drawings:

FIG. 1 is a fragmentary, partly sectional, schematic view to illustrate testing of a conventional compliant bump bumped integrated circuit device with the use of a probe;

FIG. 2 is a schematic view of the preferred embodiment of an integrated circuit device according to this invention;

FIG. 3 is a fragmentary, partly sectional view of the preferred embodiment of a compliant bump of the integrated circuit device;

FIG. 4 is a schematic view to illustrate the configuration of a pattern of recesses formed in an probe-contacting surface of a compliant bump of the preferred embodiment;

FIG. 5 is a schematic view to illustrate the configuration of another pattern of recesses formed in the probe-contacting surface of the compliant bump of the preferred embodiment;

FIG. 6 is a flow diagram illustrating consecutive steps of the first preferred embodiment of a method for forming the compliant bumps of the integrated circuit device according to this invention;

FIGS. 7 to 13 are schematic, partly sectional views to illustrate the consecutive steps of the method of the first preferred embodiment;

FIG. 14 is a fragmentary, partly sectional view of the integrated circuit device modified from the previous embodiment shown in FIG. 3;

FIG. 15 is a flow diagram illustrating consecutive steps of the second preferred embodiment of the method for forming the compliant bumps of the integrated circuit device according to this invention;

FIGS. 16 to 21 are schematic, partly sectional views to illustrate the consecutive steps of the method of the second preferred embodiment;

FIG. 22 is a flow diagram illustrating consecutive steps of the third preferred embodiment of the method for forming the compliant bumps of the integrated circuit device according to this invention; and

FIGS. 23 to 28 are schematic, partly sectional views to illustrate the consecutive steps of the method of the third preferred embodiment.

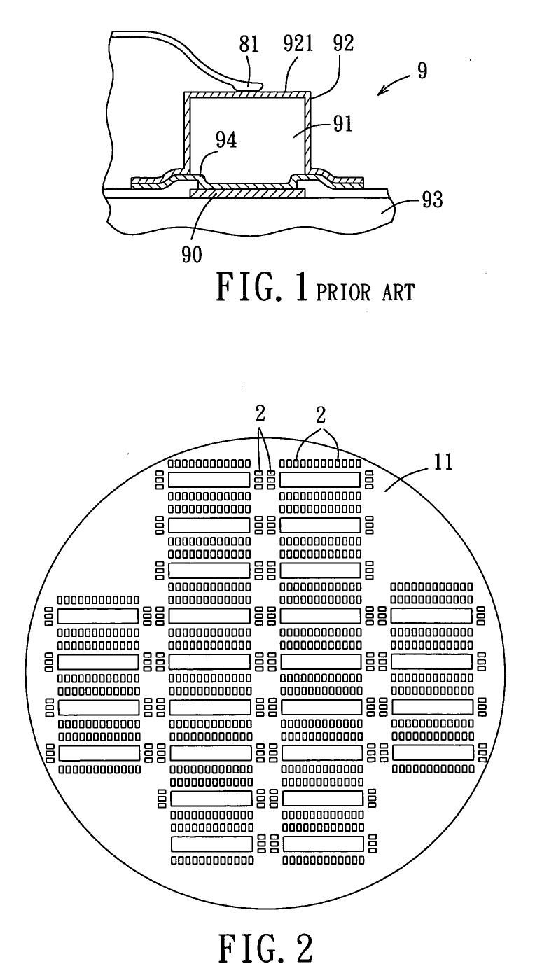

### DETAILED DESCRIPTION OF THE PREFERRED EMBODIMENTS

Before the present invention is described in greater detail, it should be noted that same reference numerals have been used to denote like elements throughout the specification.

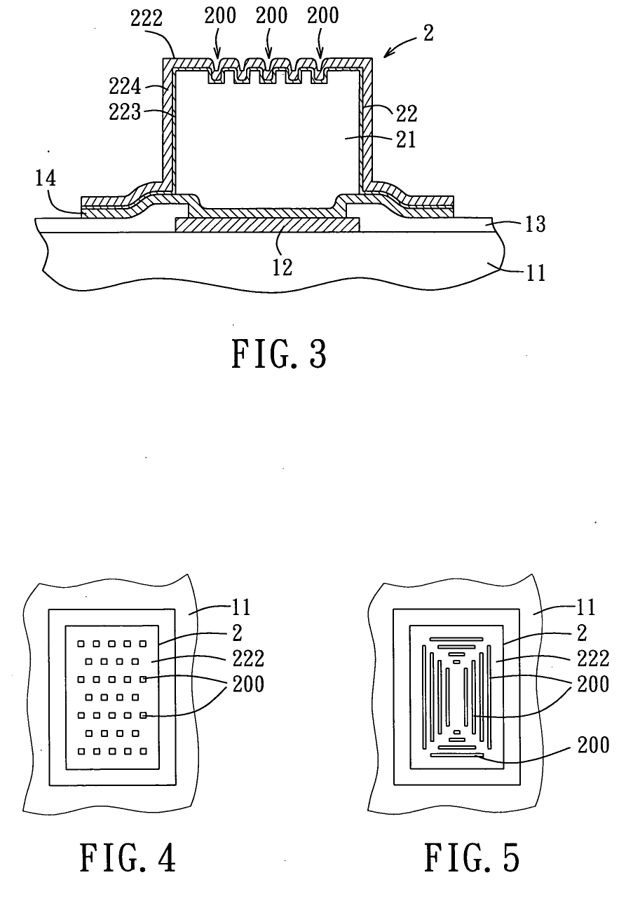

FIGS. 2 and 3 illustrate the preferred embodiment of an integrated circuit device, such as a wafer with circuits formed therein, according to this invention.

The integrated circuit device includes a substrate 11 having a pad-mounting surface and a plurality of bonding pads 12 formed on the pad-mounting surface, and a plurality of compliant bumps 2 formed respectively on the bonding pads 12. Note that a protective layer 13 and a pad-extension layer 14 (see FIG. 3) are normally provided around each of the bonding pads 12. Each compliant bump 2 is indirectly connected to and formed on the respective bonding pad 12 through the pad-extension layer 14. Preferably, the pad-extension layer 14 is built with TiW alloy.

Each of the compliant bumps 2 has a polymeric body 21 formed on the respective one of the bonding pads 12, and a metal layer 22 formed on the polymeric body 21. The metal layer 22 of each of the compliant bumps 2 has a probe-contacting surface 222 that is formed with a plurality of recesses 200.

When the integrated circuit device undergoes electrical test in a testing method for testing electrical continuity between the metal layer 22 of each of the compliant bumps 2 and a corresponding circuit of the integrated circuit device by contacting a probe (not shown) of a testing apparatus with the probe-contacting surface 222 of the metal layer 22, the recesses 200 provide a surface roughness that is sufficient to prevent the probe from slipping on the probe-contacting surface 22s of the metal layer 22, thereby eliminating the aforesaid drawbacks associated with the prior art.

Preferably, the metal layer 22 includes an inner sub-layer 223 formed on the polymeric body 21 and made from a metal selected from the group consisting of Cr, Ti, Ni, Al, and TiW, and an outer sub-layer 224 formed on the inner sub-layer 223 and made from a metal selected from the group consisting of Au and Cu. Preferably, the inner sub-layer 223 of the metal layer 22 has a thickness of about 1500 angstroms, whereas the outer sub-layer 224 of the metal layer 22 has a thickness of about 2500 angstroms.

The polymeric body 21 can be made from a photoresist material or a non-photoresist material, and is preferably made from a material selected from the group consisting of polyimide, benzocyclobutene, polyacrylates, rubber, and silicone.

In this embodiment, the recesses 200 in the probe-contacting surface 222 of the metal layer 22 are in the form of dots, as best shown in FIG. 4. In a modified embodiment, the recesses 200 in the probe-contacting surface 222 of the metal layer 22 are in the form of elongated strips, as best shown in FIG. 5.

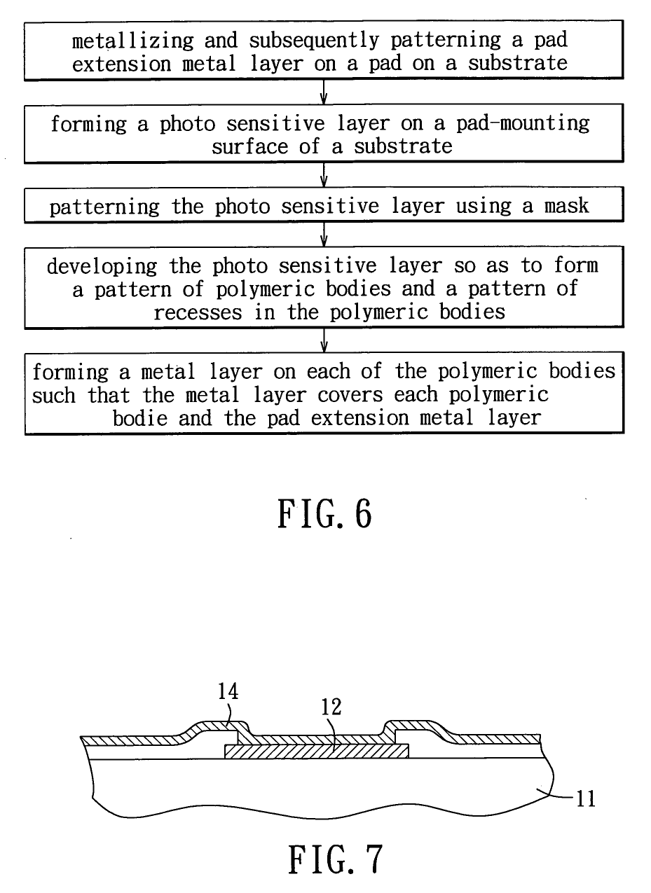

FIGS. 6 to 13 illustrate consecutive steps of the first preferred embodiment of a method for forming the compliant bumps 2 of the integrated circuit device according to the present invention.

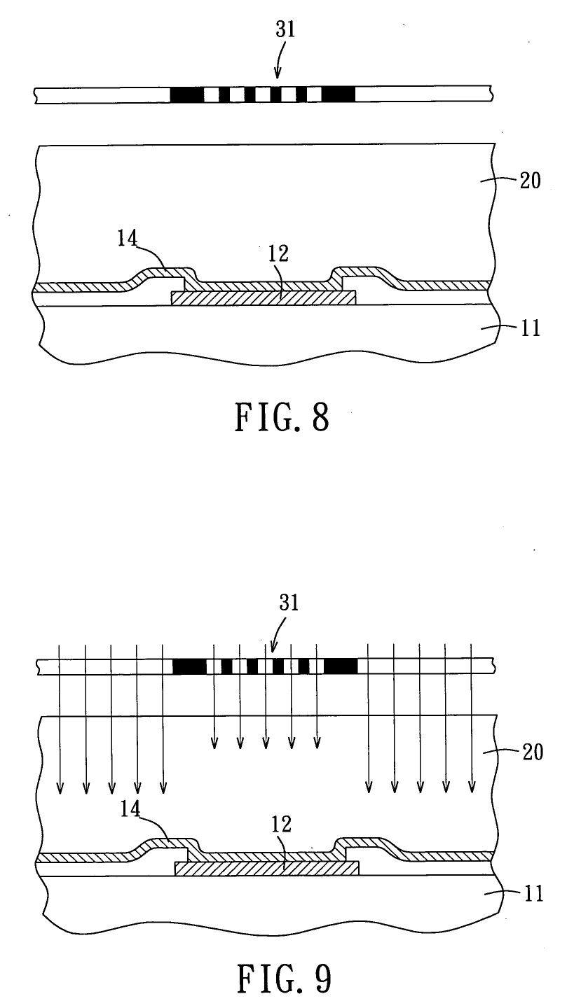

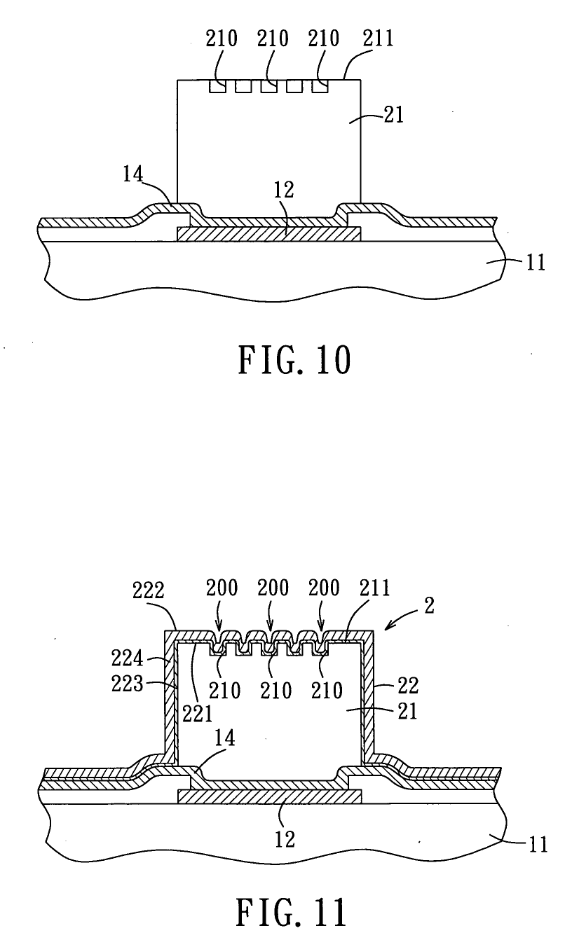

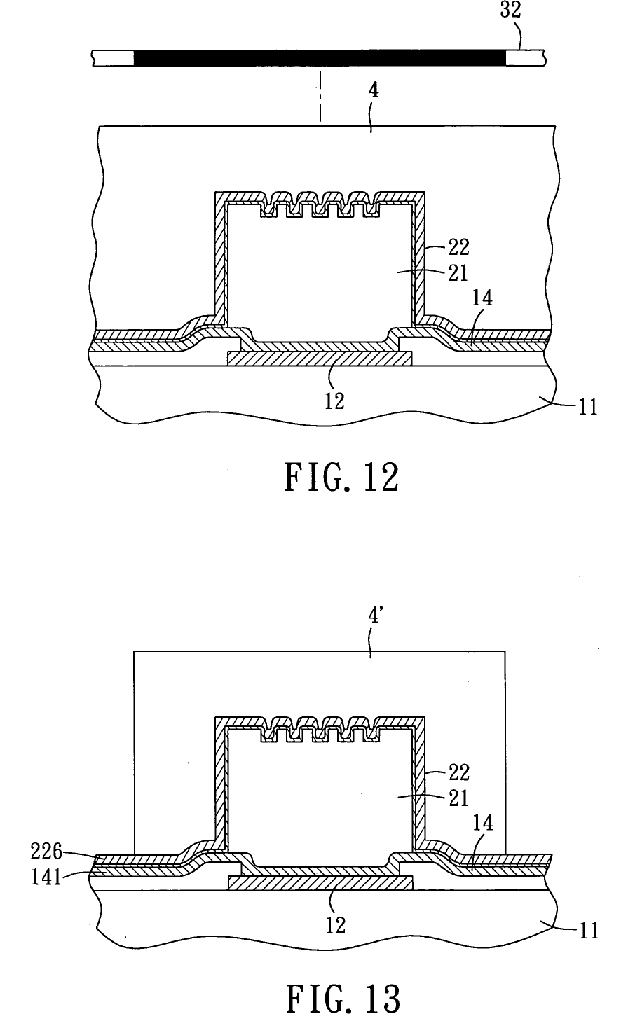

The method includes the steps of: forming a pad-extension layer 14 on the bonding pads 12 for extension of each bonding pad 12 for connecting to a compliant bump 2 to be formed thereon (see FIG. 7); forming a photo sensitive material layer 20 on the pad-extension layer 14 on the pad-mounting surface of the substrate 11 such that the photo sensitive material layer 20 is coated over the bonding pads 12 (see FIG. 8); patterning the photo sensitive material layer 20 using a first mask 31 to define a predetermined pattern of bump areas on the photo sensitive material layer 20 and a predetermined pattern of recess areas on each of the bump areas through photolithography techniques (see FIGS. 8 and 9), the photo sensitive material layer 20 outside the bump areas being fully exposed to light, and the recess areas on the photo sensitive material layer 20 being partially exposed due to limited opening area during the exposure operation; developing the photo sensitive material layer 20 using a developer solution to remove the photo sensitive material layer 20 at the exposed area so as to form a predetermined pattern of polymeric bodies 21 coated respectively over the bonding pads 12 and a predetermined pattern of recesses 210 in an upper surface 211 of each of the polymeric bodies 21 (see FIG. 10), the photo sensitive material employed in this embodiment being polyimide; forming a metal layer 22 on each of the polymeric bodies 21 (see FIG. 11) such that the metal layer 22 is electrically connected to a corresponding one of the bonding pads 12 through the pad-extension layer 14 and that the metal layer 22 covers and conforms to the outer surface 211 of each of the polymeric bodies 21 so as to form the recesses 200 in the probe-contacting surface 222 of the metal layer 22, the metal layer 22 including inner and outer sub-layers 223, 224 which are formed by sputtering techniques, the metal layer 22 cooperating with the respective polymeric body 21 to form the respective compliant bump 2; forming a photoresist layer 4 on the pad-mounting surface of the substrate 11 and the compliant bumps 2 (see FIG. 12); patterning the photoresist layer 4 using a second mask 32 to define bump areas on the photoresist layer 4 through photolithography techniques such that the remaining area on the photoresist layer 4 is fully exposed to light, each bump area covering a respective compliant bump 2 and a periphery of a respective bonding pad 12 (see FIG. 12); developing the photoresist layer 4 to remove the photoresist layer 4 at the exposed area so as to form a shielding layer 4′ (see FIG. 13) on the compliant bumps 2 and so as to expose an excess portion 226 of the metal layer 22 around the respective compliant bump 2; removing the excess portion 226 of the metal layer 22 and an excess portion 141 of the pad-extension layer 14 by etching; and removing the shielding layer 4′ from each of the compliant bumps 2.

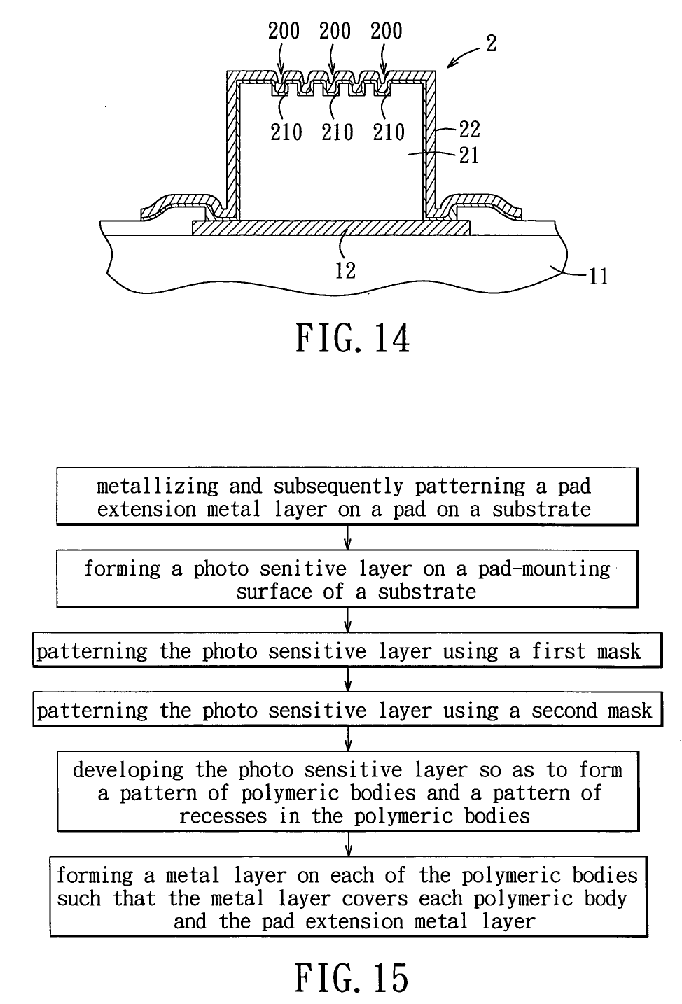

FIG. 14 illustrates the configuration of the integrated circuit device modified from the previous embodiment shown in FIG. 3. The modified integrated circuit device differs from the previous embodiment in that each complaint bump 2 is directly formed on the respective bonding pad 12.

FIGS. 15 to 21 illustrate consecutive steps of the second preferred embodiment of the method for forming the compliant bumps 2 of the integrated circuit device of FIG. 14 according to the present invention.

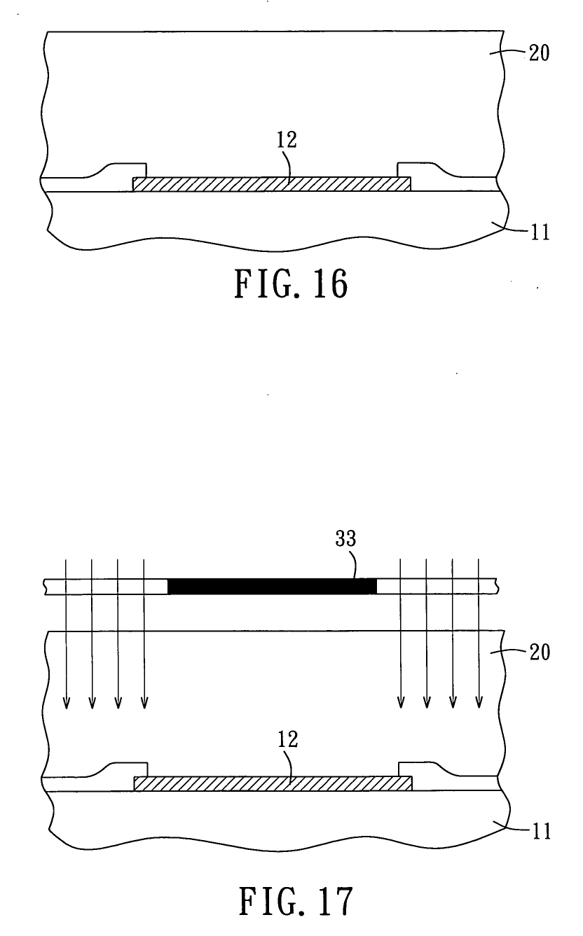

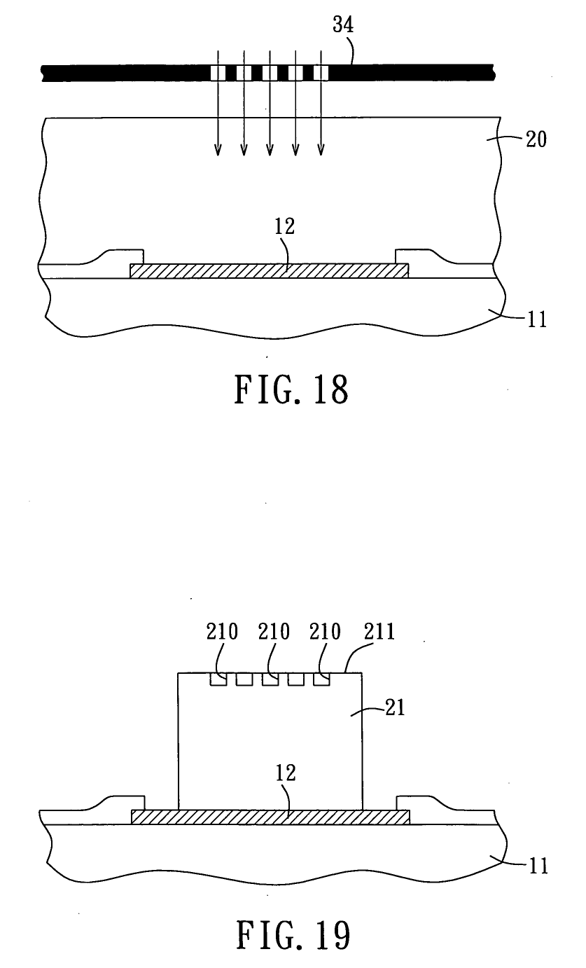

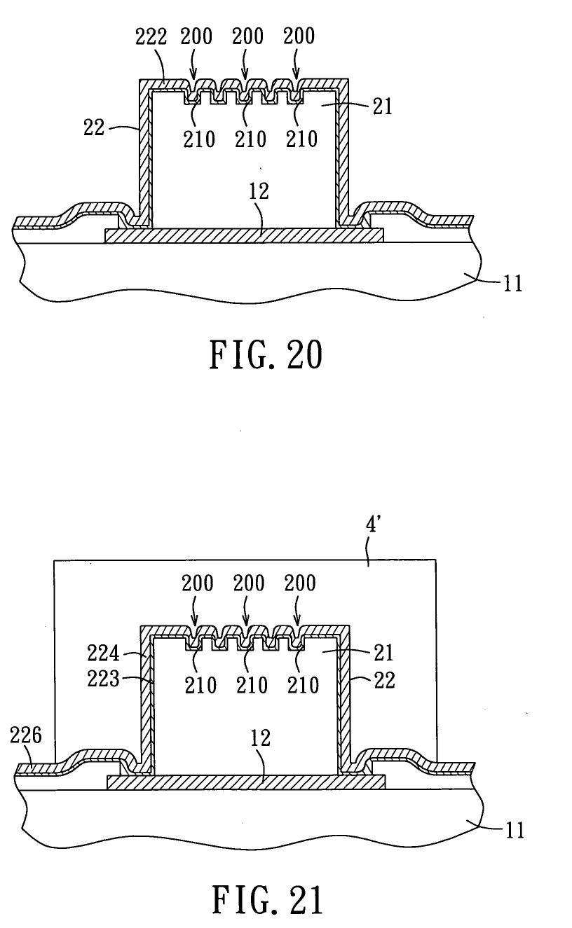

The method of this embodiment includes the steps of: forming a photo sensitive layer 20 on the pad-mounting surface of the substrate 11 such that the photo sensitive layer 20 is formed on the bonding pads 12 (see FIG. 16); patterning the photo sensitive layer 20 using a first mask 33 to define a predetermined pattern of bump areas on the photo sensitive layer 20 through photolithography techniques (see FIG. 17); further patterning the photo sensitive layer 20 using a second mask 34 to define a predetermined pattern of recess areas on each of the bump areas through photolithography techniques (see FIG. 18); developing the photo sensitive layer 20 so as to form a predetermined pattern of polymeric bodies 21 on the bonding pads 12 and a predetermined pattern of recesses 210 in an upper surface 211 of each of the polymeric bodies 21 (see FIG. 19); forming a metal layer 22 on each of the polymeric bodies 21 (see FIG. 20) such that the metal layer 22 is electrically connected to a periphery of a corresponding one of the bonding pads 12 and such that the metal layer 22 covers and conforms to an outer surface of each of the polymeric bodies 21 so as to form the recesses 200 in the probe-contacting surface 222 of the metal layer 22, the metal layer 22 including the inner and outer sub-layers 223, 224 and being formed by sputtering techniques; and removing an excess portion 226 of the metal layer 22 around the respective compliant bump 2 by etching (see FIG. 21). The process for removing the excess portion 226 of the metal layer 22 in the method of this embodiment is similar to that of the method of the first preferred embodiment.

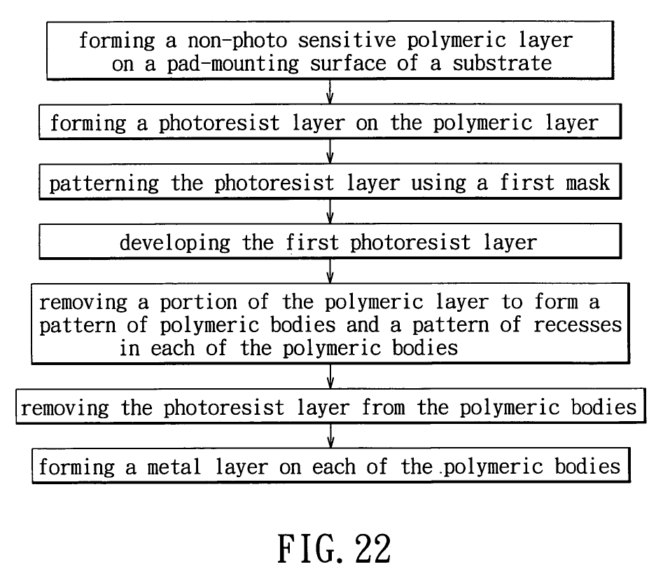

FIG. 22 to 28 illustrate consecutive steps of the third preferred embodiment of the method for forming the compliant bumps 2 of the integrated circuit device of FIG. 14 according to the present invention. Note that the polymeric body 21 of each of the compliant bumps 2 formed by the method of this embodiment is made from a non-photo sensitive material, such as non-photosensitive polyimide.

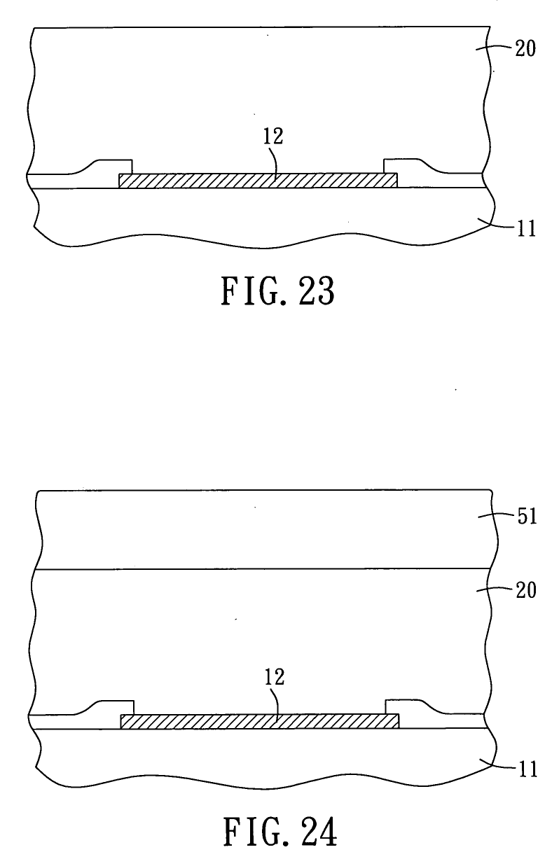

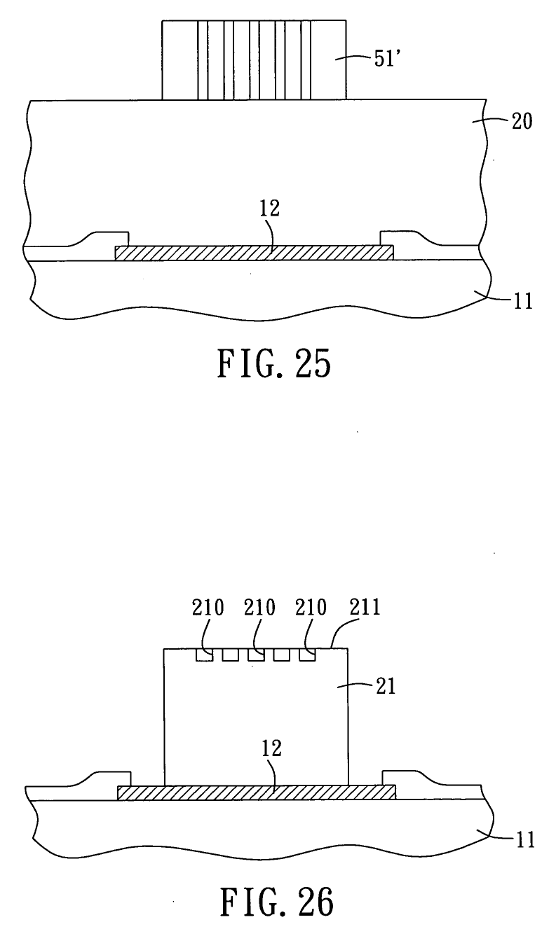

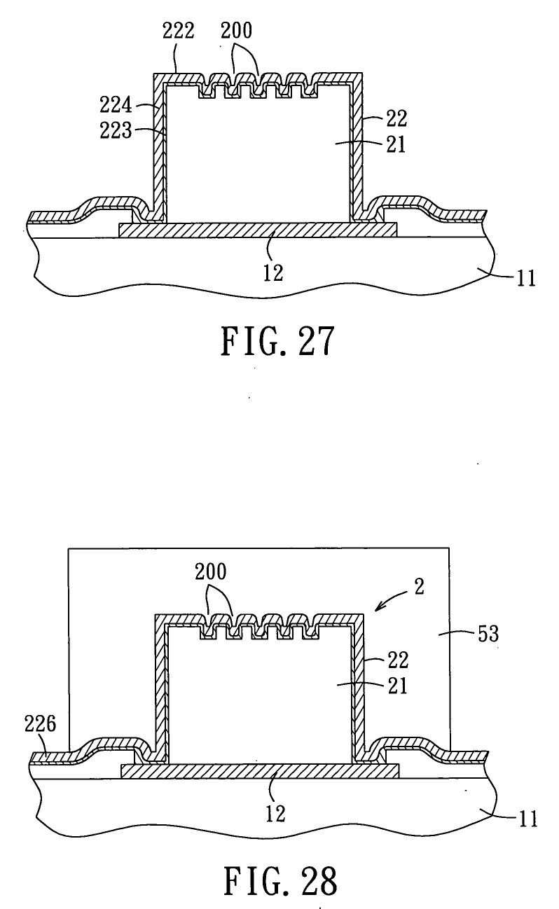

The method of this embodiment includes the steps of: forming a polymeric layer 20 (which is made from non-photosensitive polyimide in this embodiment) on the pad-mounting surface of the substrate 11 (see FIG. 23) such that the polymeric layer 20 is formed on the bonding pads 12 on the pad-mounting surface of the substrate 11; forming a photoresist layer 51 on the polymeric layer 20 (see FIG. 24); patterning the photoresist layer 51 using a mask (not shown) to simultaneously define a predetermined pattern of bump areas and a predetermined pattern of recess areas on the polymeric layer 20 through photolithography techniques (see FIG. 25); developing the photoresist layer 51 so as to expose etching areas on the polymeric layer that respectively correspond to peripheries of the bump areas and the recess areas; removing the polymeric layer 20 at the exposed area by etching so as to form a predetermined pattern of polymeric bodies 21 and a predetermined pattern of recesses 210 in the upper surface 211 of each of the polymeric bodies 21 (see FIG. 26); removing the photoresist layer 51 from the polymeric bodies 21 (see FIG. 26); forming a metal layer 22 on each of the polymeric bodies 21 such that the metal layer 22 is electrically connected to a corresponding one of the bonding pads 12 and such that the metal layer 22 covers and conforms to an outer surface of each of the polymeric bodies 21 so as to form the recesses 200 in the probe-contacting surface 222 of the metal layer 22 (see FIG. 27), the metal layer 22 including the inner and outer sub-layers 223, 224 and being formed by sputtering techniques; and removing an excess portion 226 of the metal layer 22 around the respective compliant bump 2 by etching (see FIG. 28). Note that a second photoresist layer 52 is used for shielding the compliant bumps 2 during removal of the excess portion 226 of the metal layer 22. The process for removing the excess portion 226 of the metal layer 22 in the method of this embodiment is similar to those of the method of the first and second preferred embodiments.

By forming the recesses 200 in the probe-contacting surface 222 of the metal layer 22 of the compliant bump 2 according to the method for forming the integrated circuit device of this invention, the aforesaid drawbacks associated with the prior art during electrical test can be eliminated.

While the present invention has been described in connection with what is considered the most practical and preferred embodiments, it is understood that this invention is not limited to the disclosed embodiments but is intended to cover various arrangements included within the spirit and scope of the broadest interpretations and equivalent arrangements.

1. A testing method for testing electrical continuity between compliant bumps and circuits of an integrated circuit device, the testing method comprising the steps of:
forming the compliant bumps on bonding pads on a substrate of the integrated circuit device such that each of the compliant bumps has a polymeric body formed on a corresponding one of the bonding pads and a metal layer formed on the polymeric body, and such that the metal layer has a probe-contacting surface formed with a plurality of recesses; and
testing electrical continuity between the metal layer of each of the compliant bumps and a corresponding one of the circuits of the integrated circuit device by contacting a probe of a testing apparatus with the recessed probe-contacting surface of the metal layer which provides a surface roughness that is sufficient to prevent the probe from slipping on the probe-contacting surface of the metal layer during testing by virtue of the recesses formed in the probe-contacting surface of the metal layer.

2. The testing method of claim 1, wherein the compliant bumps are formed by the following steps:
forming a photo sensitive layer on a pad-mounting surface of the substrate such that the photo sensitive layer is disposed over the bonding pads;
patterning the photo sensitive layer using a mask to define a predetermined pattern of bump areas on the photo sensitive layer and a predetermined pattern of recess areas on each of the bump areas through photolithography techniques;
developing the photo sensitive layer so as to form a predetermined pattern of polymeric bodies disposed respectively over the bonding pads and a predetermined pattern of recesses in an upper surface of each of the polymeric bodies; and
forming a metal layer on each of the polymeric bodies such that the metal layer is electrically connected to a corresponding one of the bonding pads and that the metal layer covers and conforms to the outer surface of each of the polymeric bodies so as to form the recesses in the probe-contacting surface of the metal layer.

3. The testing method of claim 1, wherein the compliant bumps are formed by the following steps:
forming a photo sensitive layer on a pad-mounting surface of the substrate such that the photo sensitive layer is formed on the bonding pads;
patterning the photo sensitive layer using a first mask to define a predetermined pattern of bump areas on the photo sensitive layer through photolithography techniques;
further patterning the photo sensitive layer using a second mask to define a predetermined pattern of recess areas on each of the bump areas through photolithography techniques;
developing the photo sensitive layer so as to form a predetermined pattern of polymeric bodies on the bonding pads and a predetermined pattern of recesses in an upper surface of each of the polymeric bodies; and
forming a metal layer on each of the polymeric bodies such that the metal layer is electrically connected to a corresponding one of the bonding pads and that the metal layer covers and conforms to the outer surface of each of the polymeric bodies so as to form the recesses in the probe-contacting surface of the metal layer.

4. The testing method of claim 1, wherein the compliant bumps are formed by the following steps:
forming a polymeric layer on a pad-mounting surface of the substrate such that the polymeric layer is formed on the bonding pads on the pad-mounting surface of the substrate;
forming a photoresist layer on the polymeric layer;
patterning the photoresist layer using a mask to define a predetermined pattern of bump areas and a predetermined pattern of recess areas on the polymeric layer through photolithography techniques;
developing the photoresist layer so as to expose etching areas on the polymeric layer that respectively correspond to peripheries of the bump areas and the recess areas;
removing the polymeric layer at the etching areas by etching so as to form a predetermined pattern of polymeric bodies and a predetermined pattern of recesses in an upper surface of each of the polymeric bodies;
removing the photoresist layer from the polymeric bodies; and
forming a metal layer on each of the polymeric bodies such that the metal layer is electrically connected to a corresponding one of the bonding pads and that the metal layer covers and conforms to the outer surface of each of the polymeric bodies so as to form the recesses in the probe-contacting surface of the metal layer.

5. An integrated circuit device comprising:
a substrate having a pad-mounting surface and a plurality of bonding pads formed on said pad-mounting surface; and
a plurality of compliant bumps formed respectively on said bonding pads, each of said compliant bumps having a polymeric body formed on the respective one of said bonding pads, and a metal layer formed on said polymeric body;
wherein said metal layer of each of said compliant bumps has a probe-contacting surface that is formed with a plurality of recesses.

6. The integrated circuit device of claim 5, wherein said metal layer includes an inner sub-layer formed on said polymeric body and made from a metal selected from the group consisting of Cr, Ti, Ni, Al, and TiW, and an outer sub-layer formed on said inner sub-layer and made from a metal selected from the group consisting of Au and Cu.

7. The integrated circuit device of claim 5, wherein said polymeric body is made from a photo sensitive material.

8. The integrated circuit device of claim 5, wherein said polymeric body is made from a material selected from the group consisting of polyimide, benzocyclobutene, polyacrylates, rubber, and silicone.

9. The integrated circuit device of claim 5, wherein said recesses in said probe-contacting surface of said metal layer are in the form of elongated strips.

10. The integrated circuit device of claim 5, wherein said recesses in said probe-contacting surface of said metal layer are in the form of dots.
